(19) United States
(12) Patent Application Publication
(10) Pub. No.: US 2026/0093864 A1
(43) Pub. Date: Apr. 2, 2026

(54) SIMULATION MODEL CONSTRUCTION METHOD AND SIMULATION METHOD

(71) Applicant: MITSUBISHI HEAVY INDUSTRIES, LTD., Tokyo (JP)

(72) Inventors: Ryo Sase, Tokyo (JP); Kei Moriyama, Tokyo (JP)

(73) Assignee: MITSUBISHI HEAVY INDUSTRIES, LTD., Tokyo (JP)

(21) Appl. No.: 19/111,659

(22) PCT Filed: Sep. 27, 2023
(86) PCT No.: PCT/JP2023/035085

§ 371 Date: Mar. 13, 2025

(30) Foreign Application Priority Data
Oct. 12, 2022 (JP) 2022-163670

(51) Int. Cl. G06F 30/20

(52) U.S. Cl. CPC G06F 30/20

(57) ABSTRACT

A simulation model construction method, for constructing a simulation model which simulates input-output characteristics of a device and includes a physical model of the device, includes: preparing a plurality of pieces of input data to be input into the simulation model; generating a dataset including the plurality of pieces of input data and an output error relative to a measured value of an output value of the simulation model when each of the plurality of pieces of input data is input into the simulation model; generating a response surface of the output error for the input data, on the basis of the dataset; identifying a feature point where the output error is smallest on the response surface; generating an updated dataset by adding the feature point to the dataset; and optimizing a physical parameter included in the physical model using the updated dataset.

### TECHNICAL FIELD

This disclosure relates to a simulation model construction method and a simulation method.

The present application claims priority based on Japanese Patent Application No. 2022-163670 filed on Oct. 12, 2022, the entire content of which is incorporated herein by reference.

### BACKGROUND ART

In the development of control controllers for controlling devices, simulation technology that models devices to be controlled is often used. As this type of simulation technology, Software In the Loop Simulation (SILS) and Hardware In the Loop Simulation (HILS) are known for simulating the dynamic characteristics of devices. In SILS, the simulation is performed with a simulation model in which devices and control controllers are modeled and coupled. In HILS, the simulation is performed by coupling modeled devices with actual controllers.

In such simulation technology, if the dynamic characteristics of a device to be controlled can be accurately reproduced, the reliability of operation verification using the simulation will also improve. Therefore, the model accuracy of the control target is an important factor. Models that reproduce the dynamic characteristics of devices include, broadly speaking, physical models based on physical equations and statistical models that statistically process and reproduce the behavior of measured values. Physical models have the advantage that their physical meaning is clear, and they can be constructed even when measured values are not available. However, in order to obtain a highly accurate model, it takes effort to tune physical parameters contained in the physical model. On the other hand, statistical models have the advantage that the behavior of devices can be reproduced as long as measured values are available, but their physical meaning is unknown, and their explanatory power is poor. Thus, physical and statistical models have advantages and disadvantages over each other and should be used appropriately.

An example of the method for obtaining a model that can accurately reproduce the behavior of a device is described in Non-Patent Document 1. In this document, on the basis of a physical model with excellent explainability, a steady error model for predicting errors (steady errors) of a device in the steady state is used in combination with a transient error model for predicting errors (transient errors) of a device in the transient state. This model is supposed to accurately reproduce the behavior of the device by correcting the prediction results of the physical model for steady errors and transient errors.

### CITATION LIST

### Patent Literature

Patent Document 1: JP2020-165341A

### Non-Patent Literature

Non-Patent Document 1: Kawaguchi et al., Kernel Identification Method of Error Model in Engine Model Identification, Transactions of the Society of Instrument and Control Engineers, Vol. 50, No. 3, pp 311-317, 2014

### SUMMARY

### Problems to be Solved

Non-Patent Document 1 is based on a physical model, and the simulation results of the physical model are corrected for steady errors and transient errors to improve the prediction accuracy. However, Non-Patent Document 1 assumes a simplified model, such as a polynomial, as the physical model on which it is based. When based on such a simplified physical model, it is difficult to accurately reproduce the behavior of a device, even if correction is made for steady errors and transient errors. A physical model sufficient to reproduce the behavior of a device generally contains a large number of physical parameters, and how these physical parameters are tuned is important for constructing a reliable simulation model.

At least one embodiment of the present disclosure was made in view of the above circumstances, and an object thereof is to provide a simulation model construction method whereby it is possible to construct a simulation model that can accurately predict the behavior of a device by suitably adjusting parameters of a physical model included in the simulation model, and to provide a simulation method.

### Solution to the Problems

In order to solve the above-described problems, a simulation model construction method according to at least one embodiment of the present disclosure for constructing a simulation model which simulates input-output characteristics of a device and includes a physical model of the device comprises: an input data preparation step of preparing a plurality of pieces of input data to be input into the simulation model; a dataset generation step of generating a dataset including the plurality of pieces of input data and an output error relative to a measured value of an output value of the simulation model when each of the plurality of pieces of input data is input into the simulation model: a response surface generation step of generating a response surface of the output error for the input data, on the basis of the dataset: a feature point identification step of identifying a feature point where the output error is the smallest on the response surface; a dataset updating step of generating an updated dataset by adding the feature point to the dataset: and a model optimization step of optimizing a physical parameter included in the physical model using the updated dataset. In the response surface generation step, the response surface is updated using the updated dataset as the dataset. In the feature point identification step, the feature point is updated based on the updated response surface. In the dataset updating step, the updated dataset is further updated by adding the updated feature point to the dataset.

In order to solve the above-described problems, a simulation model method according to at least one embodiment of the present disclosure simulates the behavior of a device by using the simulation model constructed by the simulation model construction method according to at least one embodiment of the present disclosure.

### Advantageous Effects

At least one embodiment of the present disclosure provides a simulation model construction method whereby it is possible to construct a simulation model that can accurately predict the behavior of a device by suitably adjusting parameters of a physical model included in the simulation model, and provides a simulation method.

### BRIEF DESCRIPTION OF DRAWINGS

FIG. 1 is a configuration diagram showing a basic configuration of the simulation model.

FIG. 2A is a diagram showing output values from the physical model compared to the actual behavior of the device.

FIG. 2B is a diagram showing transient errors corresponding to FIG. 2A.

FIG. 3 is a flowchart of the simulation model construction method according to an embodiment.

FIG. 4 is a flowchart of optimization computation of the transient error predictive model.

FIG. 5 is a diagram showing an example of the transition of predicted values of discrete transient error output from the transient error predictive model.

FIG. 6 is a diagram schematically showing the computation process of predicted values of transient error predicted by the transient error predictive model in another embodiment.

FIG. 7 is a diagram showing the transition of predicted values of transient error output from the transient error predictive model using the computation process in FIG. 6.

FIG. 8 is an example of measured data showing the transition of engine speed, load, and intake manifold pressure of a power generation gas engine over time.

FIG. 9 is a diagram showing a configuration of the simulation model that simulates the power generation gas engine.

FIG. 10A is an example of data during the load application period.

FIG. 10B is an example of data during the load cutoff period.

### DETAILED DESCRIPTION

Embodiments of the present invention will now be described in detail with reference to the accompanying drawings. It is intended, however, that unless particularly identified, dimensions, materials, shapes, relative positions and the like of components described or shown in the drawings as the embodiments shall be interpreted as illustrative only and not intended to limit the scope of the present invention.

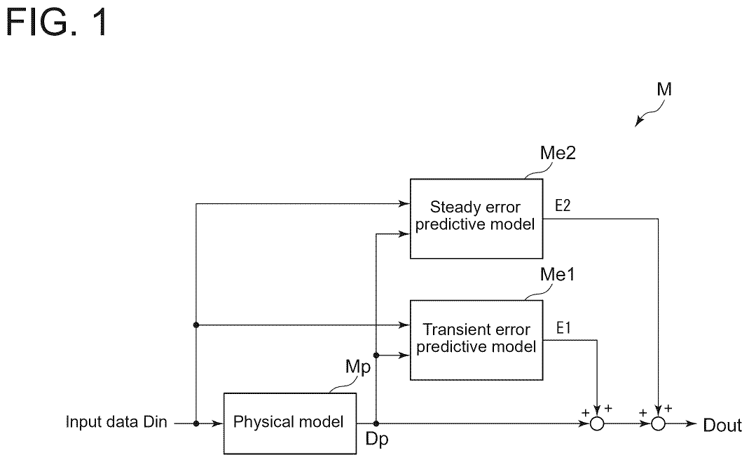

First, a basic configuration of a simulation model M constructed by the simulation model construction method according to at least one embodiment of the present disclosure will be described. FIG. 1 is a configuration diagram showing a basic configuration of the simulation model M.

The simulation model M is a model that simulates the input-output characteristics of a device in a pseudo-simulation manner. The simulated target of the simulation model M can include any device, and in particular, can include devices with highly nonlinear input-output characteristics, such as engines, for example. The use of the simulation model M is not limited, but can be used, for example, for Software In the Loop Simulation (SILS) or Hardware In the Loop Simulation (HILS) to simulate the dynamic characteristics of a device. SILS uses a simulation model M in which a device and a control controller are modeled and coupled, while HILS uses a simulation model M in which a modeled device is coupled with an actual controller.

The simulation model M includes a physical model Mp of a device to be simulated as the base model, which is its basic configuration. The physical model Mp is a model that can explain the input-output characteristics of the device structurally or physically. The physical model Mp has a clear physical meaning and can be tuned by adjusting physical parameters contained in the physical model Mp.

In this embodiment, as shown in FIG. 1, in addition to the above-described physical model Mp, the simulation model M further includes a steady error predictive model Me1 for predicting errors (steady errors) of the device in the steady state and a transient error predictive model Me2 for predicting errors of the device in the transient state. In other words, by combining the steady error predictive model Me1 and the transient error predictive model Me2 with the base physical model Mp, the simulation model M can be constructed to accurately reproduce the behavior of the device by correcting the prediction results of the physical model Mp for steady errors predicted by the steady error predictive model Me1 and transient errors predicted by the transient error predictive model Me2.

Specifically, the input data Din for the simulation model M is input to each of the physical model Mp, the steady error predictive model Me1, and the transient error predictive model Me2. The physical model Mp outputs the output data Dp corresponding to the input data Din as a prediction result. The steady error E1 corresponding to the input data Din predicted by the steady error predictive model Me1 and the transient error E2 corresponding to the input data Din predicted by the transient error predictive model Me2 are added to the output data Dp and output as the output value Dout (=Dp+E1+E2) of the simulation model M.

The transient error predictive model Me2may be a statistical model. In this case, the use of the statistical model allows construction of a simulation model M that can accurately predict a highly nonlinear target, such as engines, for example. As the statistical model, a nonlinear kernel system identification method can be used. This is advantageous in that it reduces the number of data contained in the dataset Ds and prevents over-training when constructing the simulation model M using the dataset Ds. It is also possible to use other statistical models such as AR, multiple regression, and neural networks.

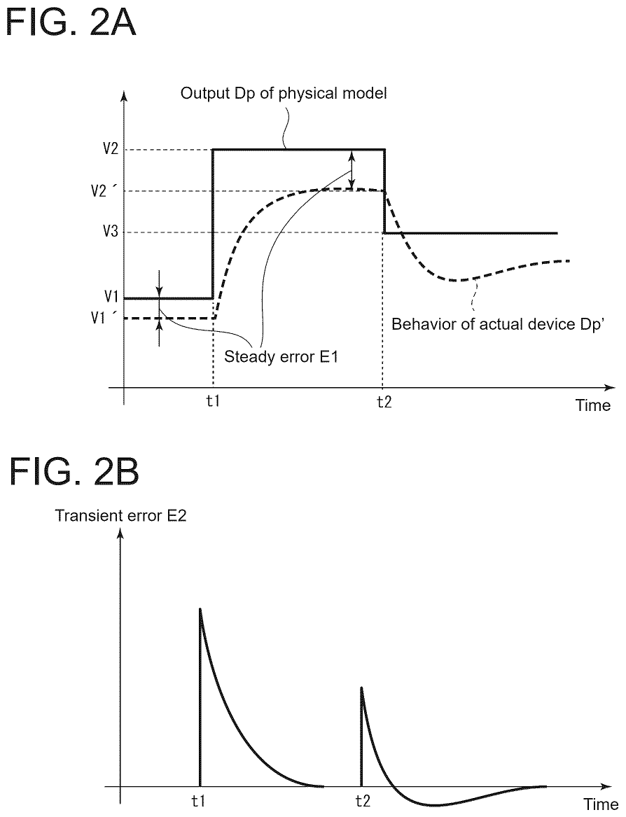

Here, FIG. 2A is a diagram showing the output value Dp from the physical model Mp compared to the actual behavior Dp′ of the device, and FIG. 2B is a diagram showing the transient error E2 corresponding to FIG. 2A.

As shown in FIG. 2A, the actual behavior Dp′ of the device remains constant at the first value V1′ before time t1 and increases asymptotically from time t1 toward the second value V2′. It remains stable at the second value V2′, then begins to decrease at time t2. In contrast, the output value Dp of the physical model Mp has the first value V1 before time t1 and changes to the second value V2 at time t1. It then changes from the second value V2 to the third value V3 at time t2. At this time, the transient error E2 is as shown in FIG. 2B. In this case, the steady error E1 transitions stepwise in such a way that it is constant before and after the boundaries of times t1 and t2, while the transient error E2 shows a rapid increase at times t1 and t2, followed by a gradual decrease.

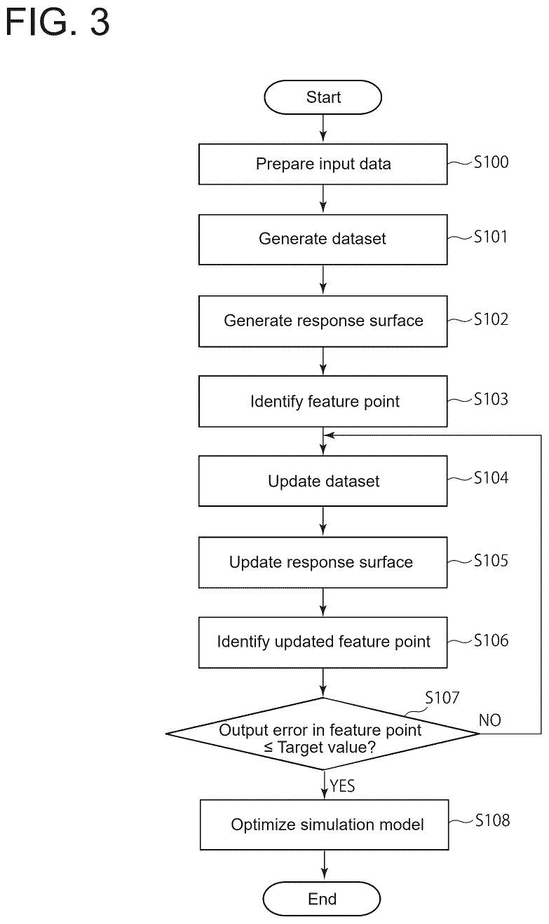

Next, the simulation model construction method for constructing the simulation model M with the above configuration will be described. FIG. 3 is a flowchart of the simulation model construction method according to an embodiment.

First, a plurality of pieces of input data Din are prepared for input to the simulation model M (step S100: input data preparation step). The plurality of pieces of input data Din are suitably selected by using, for example, an experiment design method. More specifically, Latin hypercube sampling can be used as the method for selecting the input data Din.

Then, using the plurality of pieces of input data Din prepared in step S100, a dataset Ds is generated (step S101). The dataset Ds is generated as a combination of each input data Din prepared in step S100 and an output error ΔD of the output value Dout from the simulation model M relative to the measured value when each input data Din is input to the simulation model M.

The simulation model M to which the input data Din is input in step S101 has pre-tuned model parameters in the initial state.

Then, on the basis of the dataset Ds generated in step S101, a response surface of the output error ΔD for the input data Din is generated (step S102: response surface generation step). In step S101, multiple combinations of input data Din and output error ΔD are generated as datasets Ds. In step S102, a response surface (ΔD=f(Din): f is an arbitrary function) is created by plotting these combinations in a virtual space and approximating the objective function (e.g., Gaussian process regression) based on the plotted data points.

Then, the feature point Pc where the output error ΔD is the smallest on the multiple response surfaces created in step S102 is identified by multi-objective optimization (e.g., NSGA-3) (step S103: feature point identification step). The response surface consists of a group of points where the combinations of input data Din and output error ΔD are plotted as described above, and in step S103, the one with the smallest output error ΔD among the group of points is identified as the feature point Pc.

In step S103, one feature point Pc with the smallest output error ΔD is identified from the response surface. However, one or more feature points Pc with an output error ΔD less than or equal to a predetermined threshold may be identified.

The feature point Pc identified in step S103 is then added to the dataset Ds to update the dataset Ds (step S104: dataset updating step). In other words, the number of data contained in the dataset Ds is increased by adding the data corresponding to the feature point Pc (the combination of input data Din and output error ΔD) to the original dataset Ds prepared in step S100.

The response surface is then updated using the updated dataset Ds (step S105). In step S105, a response surface is created as in step S102 previously described, but a different response surface is obtained because the original dataset Ds was updated in step S104.

The feature point Pc is then identified again based on the updated response surface (step S106). In step S106, similarly, a different feature point Pc is identified as the response surface was updated. Thus, the feature point P identified based on the response surface after the update has a smaller output error ΔD than the feature point Pc identified based on the response surface before the update. This is because the data newly added to the dataset Ds in step S104 corresponds to the smallest output error ΔD.

Next, it is determined whether the output error ΔD at the updated feature point Pc identified in step S106 is less than or equal to a preset target value (step S107). If the output error ΔD is greater than the target value (step S107: NO), the process is returned to step S104 to further add the feature point Pc identified from the updated response surface (i.e., the feature points Pc identified in step S106) to the dataset Ds to update the dataset Ds again. The above process is thus repeated based on the further updated dataset Ds, resulting in a smaller output error ΔD at the feature point Pc.

If the output error ΔD is less than or equal to the target value (step S107: YES), the simulation model M is optimized using the updated dataset Ds (step S108: model optimization step). In step S108, optimization computation is performed on the simulation model M to adjust each model parameter of the simulation model M. Specifically, the simulation model M is optimized by automatically adjusting the physical parameters contained in the physical model Mp, identifying the steady error predictive model Me1, identifying the transient error predictive model Me2, and combining these models.

In step S107, the computation (simulation computation) of output error ΔD is repeated while updating the dataset Ds until the output error ΔD is less than or equal to the target value. Since such computation is repeated until the output error ΔD falls below the target value, the number of repetitions does not need to be specified in advance by the operator.

Optimizing the simulation model M using the updated dataset Ds improves the accuracy of the base model, the physical model Mp, while reducing the dependence on the error predictive models (steady error predictive model Me1 and transient error predictive model Me2). As a result, it is possible to construct the simulation model M with favorable explainability while improving the prediction accuracy.

Further, the use of the response surface method as described above allows the simulation model M to be constructed in a practical amount of time. In particular, assuming there are multiple state quantities to be matched, multiple response surfaces may be created for the errors of each state quantity, and multi-objective optimization may be applied. This eliminates the need to adjust the weights required when the response surface is created by weighting the errors of each state quantity into a single objective function.

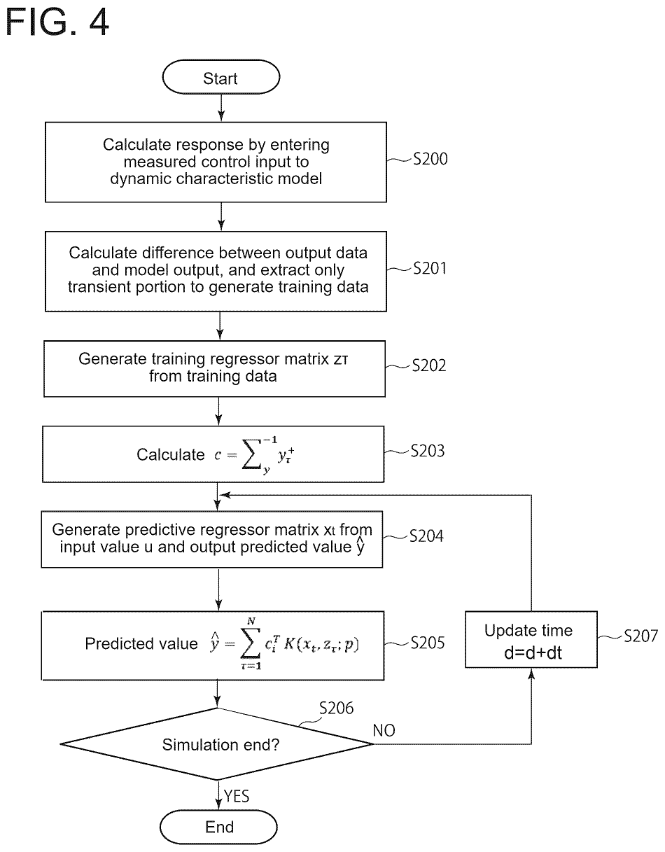

In step S108, when the nonlinear kemel system identification method is used as the statistical model for the transient error predictive model Me2 included in the simulation model M, the following optimization calculation can be performed. FIG. 4 is a flowchart of optimization calculation of the transient error predictive model Me2.

The input data Din is input to the simulation model M to calculate the output value Dout from the simulation model M (step S200).

The training data is then generated by calculating the difference between the output value Dout calculated in step S200 and the measured value corresponding to the input data Din input in step S200, and extracting a transient element from the difference (step S201).

The training regressor matrix z_{τ} is then generated from the training data generated in step S201 (step S202), and the following equation is calculated (step S203).

$$c = {\sum }_{y}^{- 1} {y}_{τ}^{+}$$

The predictive regressor matrix x_{τ} is then generated from the input value u and the output predicted value \hat{γ} (step S204), and the predicted value \hat{γ} is calculated from the following equation (step S205).

$$\hat{y} = {\sum }_{τ = 1}^{N} {c}_{i}^{τ} K ( {x}_{t} , {z}_{τ} ; p )$$

Then, it is determined whether to end the simulation (step S206). If the simulation is not to be ended (step S206: NO), the time is updated to t=t+dt (step S207), and the process returns to step S204. Conversely, if the simulation is to be ended (step S205: YES), the series of processes ends.

Steps S200 to S203 are performed offline only once before the simulation starts, and step S204 and subsequent steps are repeated for the simulation time step.

In another embodiment, when predicting the transient error E2 by the transient error predictive model Me2, the predicted value of the transient error E2 output from the transient error predictive model Me2 may be discrete in time. This is advantageous in that it greatly reduces the computational burden compared to the case where the transient error predictive model Me2 continuously calculates the predicted value of the transient error E2.

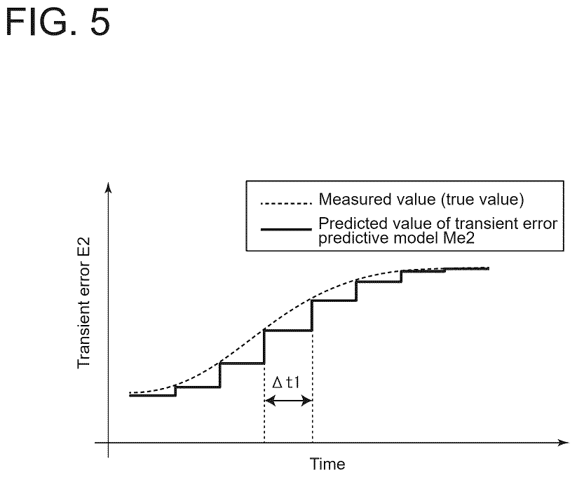

Here, FIG. 5 is a diagram showing an example of the transition of predicted values of discrete transient error E2 output from the transient error predictive model Me2. The transient error predictive model Me2 outputs predicted values of discrete transient error E2 for each first time interval Δt1. The interval between two temporally adjacent predicted values is considered constant by holding the most recent predicted value. As a result, the predicted value of the transient error E2 output from the transient error predictive model Me2 changes stepwise over time, as shown in FIG. 5. The transient error predictive model Me2 which outputs the predicted values of the transient error E2 discrete in time is advantageous in that it is less computationally burdensome, but each predicted value is held for the first time interval Δt1, resulting in a large deviation from the measured value, which causes some differences between the actual device behavior.

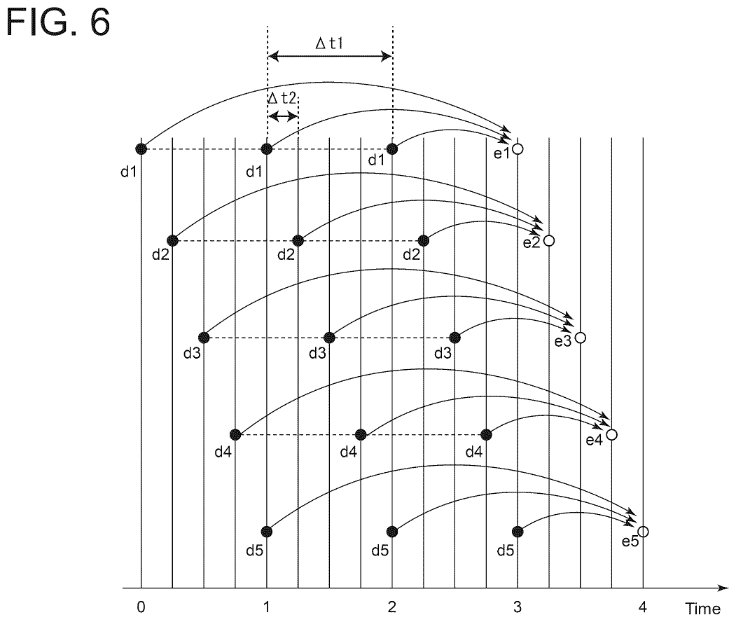

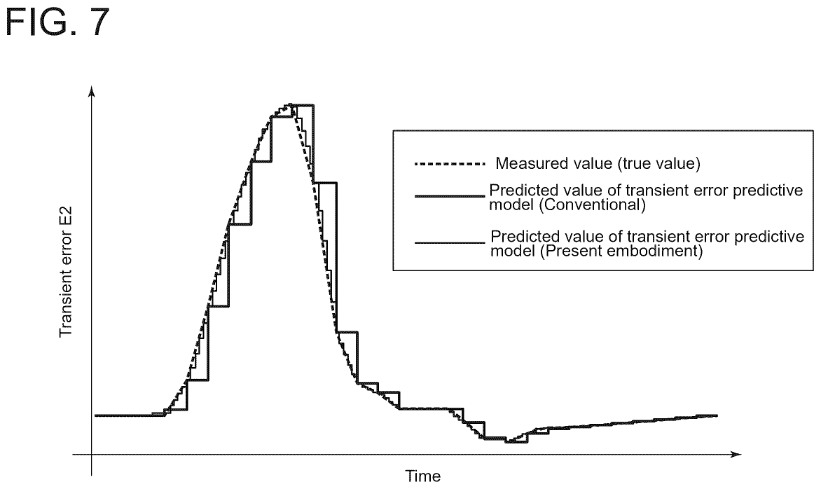

FIG. 6 is a diagram schematically showing the computation process of predicted values of transient error E2 predicted by the transient error predictive model Me2 in another embodiment. FIG. 7 is a diagram showing the transition of predicted values of transient error output from the transient error predictive model Me2 using the computation process in FIG. 6. In this embodiment, the transient error predictive model Me2 has a computation cycle of a second time period Δt2, which is shorter than the first time period Δt1, and estimates predicted values based on at least one past data in units of the first time period Δt1 from the current time. In FIG. 6, the second time period Δt2 is set to ¼ of the first time period Δt1, and the predicted value at each time is estimated based on multiple past data. For example, the predicted value e1 is estimated based on multiple past predicted values d1 for each first time period Δ1 from the predicted value e1. Then, the predicted value e2 at the time when the second time period Δ2 is advanced from the predicted value e1 is estimated based on multiple past predicted values d1 for each first time period Δ1 from the predicted value e2. As a result, as shown in FIG. 7, the predicted values of transient error E2 are relatively smooth and closer to the actual behavior than the stepwise behavior as shown in FIG. 5. This indicates that the above problem can be effectively solved by predicting time-discrete transient error E2, which reduces the computational burden, while providing accurate predictions that closely match the actual behavior.

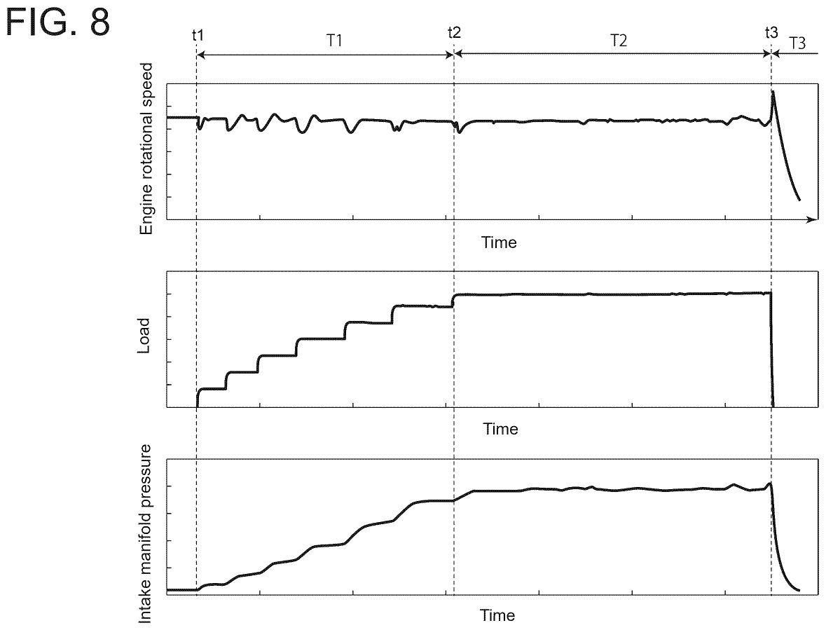

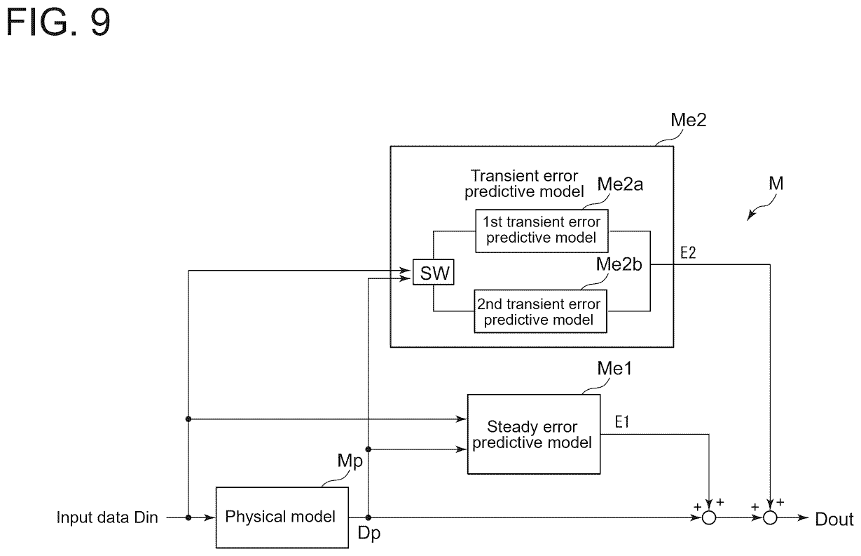

The following describes a specific example of the simulation model M that treats a power generation gas engine as the simulated target. FIG. 8 is an example of measured data showing the transition of engine speed, load, and intake manifold pressure of a power generation gas engine over time. FIG. 9 is a diagram showing a configuration of the simulation model M that simulates the power generation gas engine.

As shown in FIG. 8, the power generation gas engine is initially operated such that the engine speed is increased from a standstill state to reach the rated speed at no load. At time t1, the load begins to be applied.

During the load application period T1 from time t1 to t2, the load and intake manifold pressure change to increase gradually over time while the engine speed is held substantially constant at the rated speed. During the steady operation period T2 from time t2 to t3, the engine speed, load, and intake manifold pressure are each held substantially constant. Then, during the load cutoff period T3 after time t3, the load is cut off at time t3, so that the intake manifold pressure decreases rapidly, and the engine speed decreases gradually.

The simulation model M shown in FIG. 9 differs from FIG. 1 in that it has a first transient error predictive model Me2a and a second transient error predictive model Me2b instead of the transient error predictive model Me2. The first transient error predictive model Me2a is the transient error predictive model corresponding to the load application period T1 of the power generation gas engine, and the second transient error predictive model Me2b is the transient error predictive model corresponding to the load cutoff period T3 of the power generation gas engine. The transient error predictive model Me2 is configured to be switchable between the first transient error predictive model Me2a and the second transient error predictive model Me2b depending on whether the simulated target is in the load application period T1 or the load cutoff period T3.

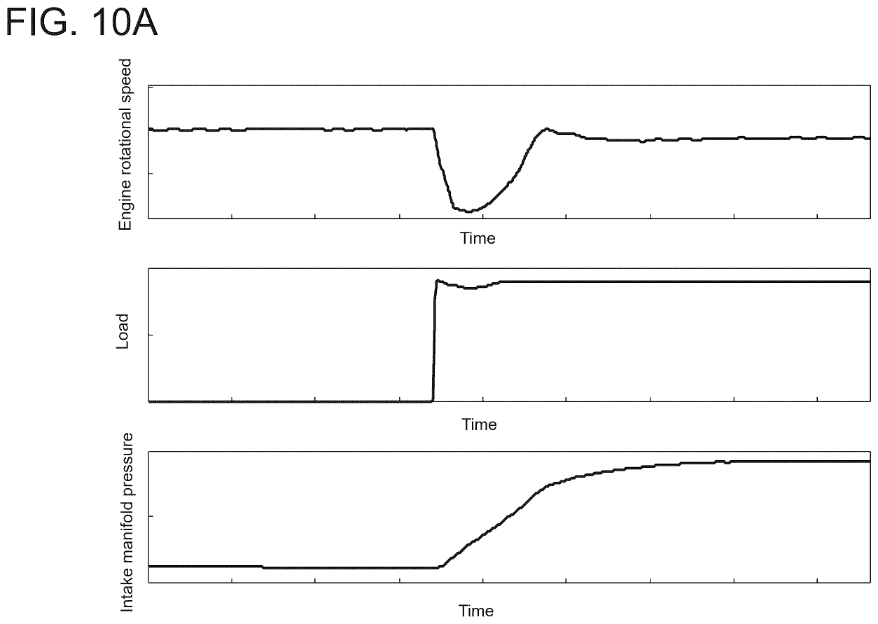

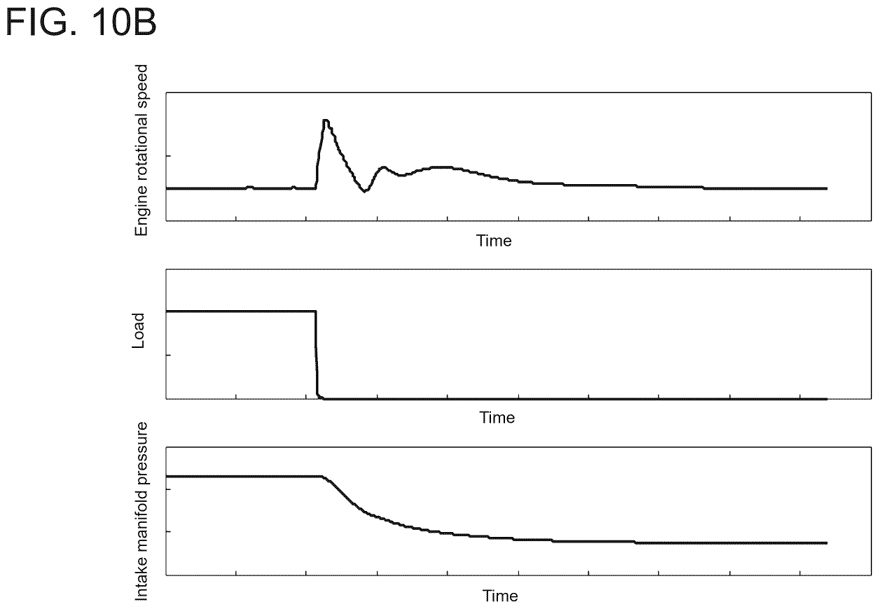

The first transient error predictive model Me2a and the second transient error predictive model Me2b are adjusted using data (including the transition of engine speed, load, and intake manifold pressure of the power generation gas engine over time as in FIG. 8) for the load application period T1 and the load cutoff period T3 shown in FIG. 10A and FIG. 10B, respectively.

In the steady operation period T2, the operating condition of the power generation gas engine is almost constant, so the transient error may be assumed to be almost zero (i.e., the transient error may be assumed to be substantially zero without prediction).

If a transient error predictive model with high generalization performance (i.e., the same regardless of the period) is used to simulate a series of behaviors of the power generation gas engine from the startup period T1 to the load cutoff period T3 with a single simulation model M, long data including non-stationary operation patterns such as the load application period T1 and the load cutoff period T3 (e.g., data as shown in FIG. 8) are required for model adjustment, which may increase the computational burden and reduce the accuracy of the model. In contrast, by making it possible to switch the model for predicting transient errors according to the period to be predicted as described above, accurate predictions can be made according to the operating conditions of the power generation gas engine, and the computational burden can be effectively reduced.

Thus, according to this embodiment, when the power generation gas engine is the simulated target, the transient error predictive model included in the simulation model is constructed to be switchable between the first transient error predictive model Me2a corresponding to the load application period T1 of the power generation gas engine and the second transient error predictive model Me2b corresponding to the load cutoff period T3 of the power generation gas engine. This allows the behavior of the power generation gas engine to be simulated more accurately by switching the transient error predictive model according to the operating conditions of the power generation gas engine.

As described above, according to the above embodiments, data corresponding to the feature point identified from the response surface of the output error for the input data is added to the dataset that includes the input data for the simulation model and the output error of the simulation model when the input data is entered, thereby updating the dataset for optimizing the physical model included in the simulation model. The updated dataset contains additional data that minimizes the output error of the simulation model, allowing the physical model to be optimized efficiently.

In addition, the components in the above-described embodiments may be appropriately replaced with known components without departing from the spirit of the present disclosure, or the above-described embodiments may be appropriately combined.

The contents described in the above embodiments would be understood as follows, for instance.
(1) A simulation model construction method according to one aspect is a method for constructing a simulation model which simulates input-output characteristics of a device and includes a physical model of the device, comprising: an input data preparation step of preparing a plurality of pieces of input data to be input into the simulation model: a dataset generation step of generating a dataset including the plurality of pieces of input data and an output error relative to a measured value of an output value of the simulation model when each of the plurality of pieces of input data is input into the simulation model: a response surface generation step of generating a response surface of the output error for the input data, on the basis of the dataset; a feature point identification step of identifying a feature point where the output error is the smallest on the response surface; a dataset updating step of updating the dataset by adding the feature point to the dataset: and a model optimization step of optimizing a physical parameter included in the physical model using the updated dataset. In the response surface generation step, the response surface is updated using the updated dataset as the dataset. In the feature point identification step, the feature point is updated based on the updated response surface. In the dataset updating step, the updated dataset is further updated by adding the updated feature point to the dataset.

With the above configuration (1), data corresponding to the feature point identified from the response surface of the output error for the input data is added to the dataset that includes the input data for the simulation model and the output error of the simulation model when the input data is entered, thereby updating the dataset for optimizing the physical model included in the simulation model. The updated dataset contains additional data that minimizes the output error of the simulation model, allowing the physical model to be optimized efficiently.

Further, the response surface is updated by generating a response surface again using the dataset to which data is newly added. The update is repeated by further adding data corresponding to the feature point identified from the updated response surface to the dataset. By iteratively updating such a dataset, it is possible to construct a dataset that can efficiently optimize the physical model.
(2) In another aspect, in the above aspect (1), in the dataset updating step, the feature point is added to the dataset until the output error corresponding to the feature point is less than or equal to a preset target value.

With the above aspect (2), the dataset is updated by adding data corresponding to the feature point to the dataset so that the output error at the feature point identified from the response surface is less than or equal to the target value. Thus, it is possible to obtain a dataset that allows efficient optimization of the physical model.
(3) In another aspect, in the above aspect (1) or (2), in the response surface generation step, the response surface is generated by Gaussian process regression using the dataset.

With the above aspect (3), the response surface can be suitably generated from the dataset by Gaussian process regression.
(4) In another aspect, in any of the above aspects (1) to (3), in the input data preparation step, the plurality of pieces of input data are selected using an experimental design method.

With the above aspect (4), the input data for the simulation model can be suitably selected by the experimental design method.
(5) In another aspect, in any one of the above aspects (1) to (4), the simulation model includes: a steady error predictive model for predicting a steady error of the physical model corresponding to the input data: and a transient error predictive model for predicting a transient error of the physical model corresponding to the input data.

With the above aspect (5), the simulation model includes the steady error predictive model for predicting a steady error of the physical model and the transient error predictive model for predicting a transient error of the physical model. Thus, by separating the error predictive model included in the simulation model for the steady error and the transient error, a model with excellent accuracy for both the steady error and transient error can be obtained (Generally, a model for predicting the steady error can be obtained relatively easily by comparison with steady test results, etc., but it is not easy to obtain an accurate model for predicting the transient error because various change patterns are assumed).
(6) In another aspect, in the above aspect (5), the transient error predictive model is a statistical model.

With the above aspect (6), the use of the statistical model as the transient error predictive model allows construction of a simulation model that can accurately predict a highly nonlinear target, such as engines, for example.
(7) In another aspect, in the above aspect (6), the statistical model uses a nonlinear kernel system identification method.

With the above aspect (7), using the nonlinear kernel system identification method as the statistical model in the transient error predictive model is advantageous in that it reduces the number of data contained in the dataset and prevents over-training when constructing the simulation model using the dataset.

It is also possible to use other statistical models such as AR, multiple regression, and neural networks.
(8) In another aspect, in the above aspect (5), the transient error predictive model calculates a predicted value of the transient error for the input data, on the basis of at least one past predicted value, in a second time period that is shorter than a first time interval at which the predicted value is calculated.

With the above aspect (8), the calculation of the predicted value of the transient error by the transient error predictive model is performed based on at least one past predicted value in the second time period that is shorter than the first time interval for calculating the predicted value of the transient error for the input data. Thus, by interpolatively estimating the predicted value of the transient error during the first time interval, the transient error can be predicted accurately while reducing the computational burden.
(9) In another aspect, in the above aspect (5), the device is a power generation gas engine, and the transient error predictive model is switchable between a first transient error predictive model corresponding to when load is applied to the power generation gas engine, and a second transient error predictive model corresponding to when load is cut off from the power generation gas engine.

With the above aspect (9), when the power generation gas engine is the simulated target, the transient error predictive model included in the simulation model is constructed to be switchable between the first transient error predictive model corresponding to the load application period of the power generation gas engine and the second transient error predictive model corresponding to the load cutoff period of the power generation gas engine. This allows the behavior of the power generation gas engine to be simulated more accurately by switching the transient error predictive model according to the operating conditions of the power generation gas engine.
(10) A simulation method according to one aspect simulates the behavior of a device by using the simulation model constructed by the simulation model construction method according to any one of the aspects (1) to (9).

With the above aspect (10), by applying the simulation model constructed in any of the above aspects to Software In the Loop Simulation (SILS) or Hardware In the Loop Simulation (HILS), etc., the dynamic characteristics of a device can be accurately simulated in the development of control controllers for controlling devices.

### REFERENCE SIGNS LIST

M Simulation model
Me1 Steady error predictive model
Me2 Transient error predictive model
Me1a First transient error predictive model
Me2b Second transient error predictive model
Mp Physical model

1. A simulation model construction method for constructing a simulation model which simulates input-output characteristics of a device and includes a physical model of the device, comprising:
an input data preparation step of preparing a plurality of pieces of input data to be input into the simulation model;
a dataset generation step of generating a dataset including the plurality of pieces of input data and an output error relative to a measured value of an output value of the simulation model when each of the plurality of pieces of input data is input into the simulation model;
a response surface generation step of generating a response surface of the output error for the input data, on the basis of the dataset;
a feature point identification step of identifying a feature point where the output error is smallest on the response surface;
a dataset updating step of generating an updated dataset by adding the feature point to the dataset; and
a model optimization step of optimizing a physical parameter included in the physical model using the updated dataset,
wherein, in the response surface generation step, the response surface is updated using the updated dataset as the dataset,
wherein, in the feature point identification step, the feature point is updated based on the updated response surface, and
wherein, in the dataset updating step, the updated dataset is further updated by adding the updated feature point to the dataset.

2. The simulation model construction method according to claim 1,
wherein, in the dataset updating step, the feature point is added to the dataset until the output error corresponding to the feature point is less than or equal to a preset target value.

3. The simulation model construction method according to claim 1,
wherein, in the response surface generation step, the response surface is generated by Gaussian process regression using the dataset.

4. The simulation model construction method according to claim 1,
wherein, in the input data preparation step, the plurality of pieces of input data are selected using an experimental design method.

5. The simulation model construction method according to claim 1,
wherein the simulation model includes:
a steady error predictive model for predicting a steady error of the physical model corresponding to the input data; and
a transient error predictive model for predicting a transient error of the physical model corresponding to the input data.

6. The simulation model construction method according to claim 5,
wherein the transient error predictive model is a statistical model.

7. The simulation model construction method according to claim 6,
wherein the statistical model uses a nonlinear kernel system identification method.

8. The simulation model construction method according to claim 5,
wherein the transient error predictive model calculates a predicted value of the transient error for the input data, on the basis of at least one past predicted value, in a second time period that is shorter than a first time interval at which the predicted value is calculated.

9. The simulation model construction method according to claim 5,
wherein the device is a power generation gas engine, and
wherein the transient error predictive model is switchable between a first transient error predictive model corresponding to when load is applied to the power generation gas engine, and a second transient error predictive model corresponding to when load is cut off from the power generation gas engine.

10. A simulation method for simulating behavior of the device by using the simulation model constructed by the simulation model construction method according to claim
